(19) United States
(12) Patent Application Publication
(10) Pub. No.: US 2025/0256944 A1
(43) Pub. Date: Aug. 14, 2025

(54) TRANSPORT SYSTEM

(71) Applicant: Samsung Electronics Co., Ltd., Suwon-si (KR)

(72) Inventors: YOUNGON OH, Suwon-si (KR); JIHUN KIM, Suwon-si (KR); SANGHYUK PARK, Suwon-si (KR)

(21) Appl. No.: 18/778,122

(22) Filed: Jul. 19, 2024

(30) Foreign Application Priority Data
Feb. 13, 2024 (KR) 10-2024-0020613

(51) Int. Cl. B66C 13/40; B66C 19/00; G05D 1/667; G05D 1/692; G05D 107/70; H01L 21/677

(52) U.S. Cl. CPC B66C 13/40; B66C 19/00; G05D 1/667; G05D 1/692; H01L 21/67733; G05D 2107/70

(57) ABSTRACT

A transport system may include a first transport unit configured to move along a travelling rail installed in a semiconductor fabrication line and transport a transport target, a second transport unit configured to autonomously travel on a floor of the semiconductor fabrication line, in a location lower than the first transport unit, a first interface installed in the first transport unit and configured to identify and communicate with the second transport unit, a second interface installed in the second transport unit and configured to identify and communicate with the first transport unit, and a controller configured to receive signals from the first interface and the second interface, generate and transmit a control signal to the first transport unit and the second transport unit, and control the transport target to be exchanged between the first transport unit and the second transport unit.

### CROSS-REFERENCE TO RELATED APPLICATION

This application claims priority to and the benefit of Korean Patent Application No. 10-2024-0020613 filed in the Korean Intellectual Property Office on Feb. 13, 2024, the entire contents of which are incorporated herein by reference.

### BACKGROUND OF THE INVENTION

### (a) Field of the Invention

The present disclosure relates to a transport system.

### (b) Description of the Related Art

In the semiconductor fabrication process, the process of supplying wafers to each process facility or transporting wafers between facilities is mainly performed by using an overhead hoist transport (OHT). The wafer is transported to the facility using a front-opening universal pod (FOUP), and the facility opens the FOUP to take out the wafer and proceed with the fabrication process.

When a semiconductor fabrication facility (FAB) becomes large or needs to use equipment located in another building, there may be limitations if only the OHT is employed. Because OHT rails are installed on the ceiling of each FAB, inter-floor connections are impossible, and connections between buildings are also limited. To overcome these limitations, devices such as conveyors, stockers, and lifters are introduced between buildings or between floors to interface between OHTs.

However, these interface devices are fixed at a particular location, so the OHT must move to that location to deliver the transport target. In addition, the ports of each interface device are limited, and if transfer commands are concentrated on a limited port, a problem may occur where the OHT is congested while moving to the port of the corresponding interface device.

### SUMMARY OF THE INVENTION

The present disclosure provides a transport system that introduces an autonomous mobile robot (AMR) as an additional interface device in a semiconductor fabrication equipment, thereby being capable of direct interface work between the overhead hoist transport (OHT) and the AMR.

However, the objective of the invention is not limited to the aforementioned one, and may be extended in various ways within the spirit and scope of the present disclosure.

A transport system may include a first transport unit configured to move along a travelling rail installed in a semiconductor fabrication line and transport a transport target, a second transport unit configured to autonomously travel on a floor of the semiconductor fabrication line, in a location lower than the first transport unit, a first interface installed in the first transport unit and configured to identify and communicate with the second transport unit, a second interface installed in the second transport unit and configured to identify and communicate with the first transport unit, and a controller configured to receive signals from the first interface and the second interface, generate and transmit a control signal to the first transport unit and the second transport unit, and control the transport target to be exchanged between the first transport unit and the second transport unit.

The first transport unit may include an overhead hoist transport (OHT).

The travelling rail may be installed on a ceiling of the semiconductor fabrication line, and the first transport unit is adjacent to the ceiling.

The second transport unit may include an autonomous mobile robot (AMR) including a shelf.

The shelf unit may include a plurality of stages that are stacked.

The shelf may have a plurality of shelf sections adjacent to each other in a horizontal direction.

The shelf unit may be moveable in and out in a horizontal direction.

A transport system may further include a gate installed on the floor of the semiconductor fabrication line and including an exit prevention bar configured to open and close.

The gate may include a stationary block to which a first end of the exit prevention bar is fixed and which is configured to pivot the exit prevention bar.

The stationary block may have a guide groove configured to guide a motion of the exit prevention bar, and may include a damper in at least one end portion of the guide groove.

The second transport unit may include a sensor configured to detect the exit prevention bar.

Each of the first interface and the second interface may include a camera or a vision sensor.

Each of the first interface and the second interface may include a parallel input/output (PIO) sensor.

The first interface and the second interface include an antenna for short-range communication and a wireless LAN card, respectively.

The controller may include a first transport unit controller configured to control the first transport unit, a second transport unit controller configured to control the second transport unit, and an upper-level material control system configured to control the first transport unit controller and the second transport unit controller together, and the first transport unit controller and the second transport unit controller are configured to communicate with each other.

A transport system may include an overhead hoist transport (OHT) configured to move along a travelling rail installed in a semiconductor fabrication line and transport a transport target, an autonomous mobile robot (AMR) configured to autonomously drive below the OHT in a vertical direction, an OHT interface installed in the OHT and configured to identify and communicate with the AMR, an AMR interface installed in the AMR and configured to identify and communicate with the OHT, and a controller configured to receive signals from the OHT interface and the AMR interface, generate and transmit a control signal to the OHT and the AMR, and control the transport target to be exchanged between the OHT and the AMR.

The AMR may include a shelf configured to store the transport target.

A transport system may further include a gate installed on the floor of the semiconductor fabrication line and including an exit prevention bar configured to open and close.

Each of the OHT interface and the AMR interface may include a camera or a vision sensor, a parallel input/output (PIO) sensor, antenna for short-range communication, and a wireless LAN card.

The controller may include an OHT controller configured to control the OHT, an AMR controller configured to control the AMR, and an upper-level material control system configured to control the OHT controller and the AMR controller together, and the OHT controller and the AMR controller are configured to communicate with each other.

A method of operating a transport system may include instructing an overhead hoist transport (OHT) that is holding a transport target to move toward a first position; detecting congestion in a traveling path of the OHT toward the first position; instructing the OHT to move to a second position different from the first position; instructing an autonomous mobile robot (AMR) to move to a third position directly underneath the second position; instructing the AMR to identify the OHT and to check whether the OHT is in the second position; instructing the OHT to check whether the AMR is in the third position; and instructing the OHT to load the transport target onto a shelf of the AMR.

According to embodiments, by enabling identification and communication between the OHT and the AMR, the OHT can connect to any location where the AMR can access and deliver the transport target such as a FOUP. Therefore, the OHT may not be limited to accessing a fixed auto port and may secure a flexible interface port.

If returns are concentrated in a specific fixed auto port, OHTs entering the same lane may wait until the work of the preceding OHT is completed, resulting in congestion. In these areas, the upper-level material control system can recognize in advance before congestion occurs and issue an order for OHT to return to AMR. This allows concentrated OHT to be dispersed and congestion to be resolved.

Additionally, if the transport target needs to be unloaded from the OHT due to a failure of the OHT, etc., the transport target can be placed on the shelf of the AMR. This enables urgent response in emergency situations and eliminates the risk caused by manual work by workers.

### BRIEF DESCRIPTION OF THE DRAWINGS

FIG. 1 is a drawing schematically showing a transport system according to an embodiment.

FIG. 2 is a perspective view showing the OHT shown in FIG. 1.

FIG. 3 is a perspective view showing the AMR shown in FIG. 1.

FIG. 4 and FIG. 5 are perspective views showing a travel-stopper applied to a transport system according to an embodiment, in which FIG. 4 shows the travel-stopper in a closed state, and FIG. 5 shows the travel-stopper in an open state.

FIG. 6 is a schematic view for explaining a control system applied to a transport system according to an embodiment.

FIG. 7 is a flowchart for explaining a transport target interface method according to another embodiment.

FIG. 8 to FIG. 13 is a drawing for explaining a transport target interface method using the transport system shown in FIG. 1.

### DETAILED DESCRIPTION OF THE EMBODIMENTS

The present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification.

Size and thickness of each constituent element in the drawings are arbitrarily illustrated for better understanding and ease of description, and the following embodiments are not limited thereto. In the drawings, the thickness of layers, films, panels, regions, etc., may be exaggerated for clarity. In the drawings, the thickness of some layers and regions may be exaggerated for ease of description.

In addition, it will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

During the semiconductor fabrication process, a wafer, reticle, or mask may be stored in a carrier and transported to each fabrication facility by an overhead hoist transport (OHT). For example, a wafer is stored in a front-opening unified pod (FOUP) or a front-opening shipping box (FOSB), and a reticle or mask may be stored in a pod. The OHT moves along a travelling rail installed on a ceiling side of a fabrication facility (FAB) and may transport the FOUP, the shipping box, or the pod to the destination.

The OHT may arrive at a load port of the fabrication equipment, and transfer a transport target such as the FOUP, the shipping box, or the pod. The fabrication equipment may open the transport target, and may proceed with the fabrication process by taking out the wafer, reticle, or mask.

A semiconductor fabrication line is a building where the semiconductor is manufactured. Multiple semiconductor fabrication lines may be formed, and each of the semiconductor fabrication lines may include a plurality of fabrication facilities (FABs). In addition, the plurality of fabrication facilities configuring the semiconductor fabrication line may be formed in a multi-floor structure. Accordingly, there are becoming more cases where it is desirable to use equipment of the fabrication facility within another building or to use equipment of the fabrication facility on another floor. To this end, a separate apparatus is needed to transfer the transport target to the OHT of another building or another floor. For example, a conveyor or stocker may be introduced between buildings, and a lifter may be introduced between floors to interface between OHTs.

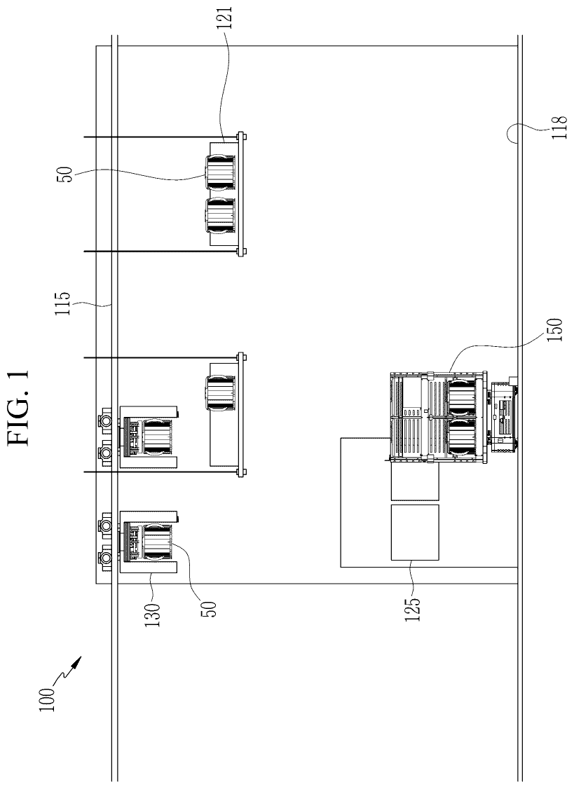

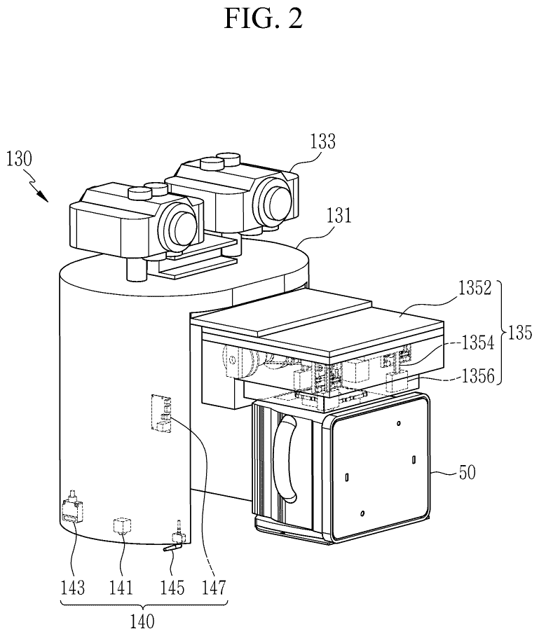

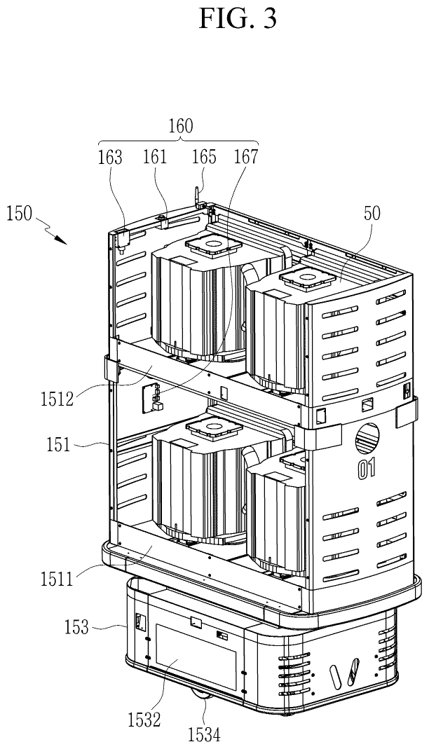

FIG. 1 is a drawing schematically showing a transport system according to an embodiment. FIG. 2 is a perspective view showing the OHT shown in FIG. 1. FIG. 3 is a perspective view showing the AMR shown in FIG. 1.

Referring to FIG. 1, a transport system 100 according to the present embodiment may include a first transport unit and a second transport unit that may identify and communicate with each other to exchange the transport target 50 within the semiconductor fabrication line. The first transport unit may be configured to move along a travelling rail 115 installed in the semiconductor fabrication line and to transport the transport target 50. The second transport unit may be configured to autonomously travel on a floor 118 of the semiconductor fabrication line, at a position lower than the first transport unit. For example, the first transport unit may include the OHT 130, and the second transport unit may include an autonomous mobile robot (AMR) 150. Hereinafter, the transport system 100 according to the present embodiment will be described in detail, taking the OHT 130 and the AMR 150 as examples. However, the present disclosure is not limited thereto.

In the semiconductor fabrication line, the travelling rail 115 may be installed on the ceiling, and accordingly, the OHT 130, which is the first transport unit may be disposed adjacent to the ceiling of the semiconductor fabrication line. In the fabrication facility (FAB) of the semiconductor fabrication line, the OHT 130 may be a material transport apparatus configured to move on the ceiling of the fabrication facility along the path of the travelling rail 115, and to transfer the transport target 50 to the load port of the facility or the target port of the material handling equipment (e.g., stocker, tower lifter, conveyor, or the like). At this time, the target port of the material handling equipment where the OHT 130 performs work may be installed close to a ceiling surface.

Referring to FIG. 2, the OHT 130 may include a body 131, a travelling unit 133, and a working unit 135, and may perform driving, loading, and unloading work of the transport target 50. The body 131 may configure an appearance of the OHT 130, and may provide a space for storing the transport target 50. The travelling unit 133 may be slidably engaged with the travelling rail 115, and may provide a driving torque capable of moving the body 131. The working unit 135 may include a hand portion 1356 for gripping the transport target 50, a hoist portion 1354 for elevating the transport target 50, and a slide portion 1352 for taking the transport target 50 in and out of the storing space of the body 131.

The hoist portion 1354 may elevate the hand portion 1356 in a vertical direction. For example, the hoist portion 1354 may lower or raise the hand portion 1356 by unwinding or winding a belt connected to the hand portion 1356. The hand portion 1356 may be detachable from the transport target 50 and may perform loading or unloading operations on the transport target 50. The slide portion 1352 may slide the hoist portion 1354 in a horizontal direction. The hand portion 1356 connected to the hoist portion 1354 may also slide in the horizontal direction.

The AMR 150, which is the second transport unit, may be disposed on the floor 118 of the semiconductor fabrication line and configured to travel above the floor 118. The AMR 150 may be a material transport apparatus configured to move on a floor surface of the fabrication facility of the semiconductor fabrication line, and to transfer the transport target 50 to the load port of the facility or the target port of the material handling equipment (e.g., stocker, tower lifter, conveyor, or the like). At this time, the target port of the material handling equipment where the AMR 150 performs work may be installed close to a floor surface.

Referring to FIG. 3, the AMR 150 may include a travelling unit 153 and a shelf unit (e.g., a shelf) 151, and may perform driving and loading and unloading work of the transport target 50. The travelling unit 153 may move above the floor 118 of the fabrication facility by using a provided wheel 1534, and may include a detecting sensor 1532 configured to identify an obstacle on a moving path. In addition, the travelling unit 153 may provide driving torque for movement to the AMR 150. The shelf unit 151 may be provided with shelves 1511 and 1512 on the travelling unit 153 and capable of storing the transport target 50.

The shelf unit 151 may include the shelves 1511 and 1512 stacked in a plurality of stages. For example, the shelf unit 151 may include the shelves 1511 and 1512 of a two-stage structure, and the shelves 1511 and 1512 in each stage may be provided with two shelf sections, such that four shelf sections in total may be included. However, the structure of the shelf unit 151 is not limited thereto, and may have a structure of three or more stages, and a shelf of each stage may laterally expand to provide three or more shelf sections, which falls within the scope of the present disclosure.

When the shelf unit 151 has a structure in which the shelves 1511 and 1512 are stacked in plural stages, an uppermost shelf 1512 may have an open front side and an open upper surface, and a lower shelf 1511 in a lower stage located below the uppermost shelf 1512 may have an open front side. At this time, the shelf 1511 of the lower stage may have a sliding structure to be configured to be capable of entering and exiting the AMR 150 in the horizontal direction toward the front side of the AMR 150.

In the transport system 100 according to the present embodiment, the first transport unit and the second transport unit may identify and communicate with each other. That is, the OHT 130 and the AMR 150 may identify and communicate with each other. To this end, the OHT 130 and the AMR 150 may include a first interface 140 and a second interface 160, respectively. That is, the first interface 140 may be installed in the OHT 130 and configured to identify and communicate with the AMR 150, and the second interface 160 may be installed in the AMR 150 and configured to identify and communicate with the OHT 130. The first interface 140 may be the OHT interface, and the second interface 160 may be an AMR interface.

The first interface 140 may include a camera or vision sensor 141, a parallel input/output (PIO) sensor 143, an antenna 145 for short-range communication, and a wireless LAN card 147. The camera or vision sensor 141 may check the shape of the AMR 150 and whether the transport target 50 exists on the shelves 1511 and 1512 of the AMR 150 through machine learning or the like. A PIO sensor 143 may communicate through a parallel input/output (PIO) communication with a PIO sensor 163 installed in the AMR 150 in advance, in order to place or lift the transport target 50 on or from the shelves 1511 and 1512 of the AMR 150.

The antenna 145 for short-range communication and the wireless LAN card 147 may check the unit name or the like by performing communication with the AMR 150 that moves below the corresponding OHT 130, in order to check whether the AMR 150 corresponds to the target unit. Information may be exchanged with wireless access point (AP) by utilizing the antenna 145 for short-range communication and the wireless LAN card 147, and the short-range communication may selectively utilize various short-range communication technologies such as Bluetooth, Wi-Fi, and ultra-wideband (UWB).

The second interface 160 may also include a camera or vision sensor 161, the PIO sensor 163, an antenna for short-range communication 165, and the wireless LAN card 167. The camera or vision sensor 161 may check the shape of the OHT 130 and whether the OHT 130 is holding the transport target 50 through machine learning or the like. The PIO sensor 163 may communicate through the PIO communication with the PIO the sensor 143 installed in the OHT 130 in advance, in order to place or lift the transport target 50 on or from the shelves 1511 and 1512 of the AMR 150.

The antenna 165 for short-range communication and the wireless LAN card 167 may check the unit name or the like by performing communication with the OHT 130 located above the corresponding AMR 150, in order to check whether the OHT 130 corresponds to the target unit. Information may be exchanged with wireless access point (AP) by utilizing the antenna 165 for short-range communication and the wireless LAN card 167, and the short-range communication may selectively utilize various short-range communication technologies such as Bluetooth, Wi-Fi, and ultra-wideband (UWB).

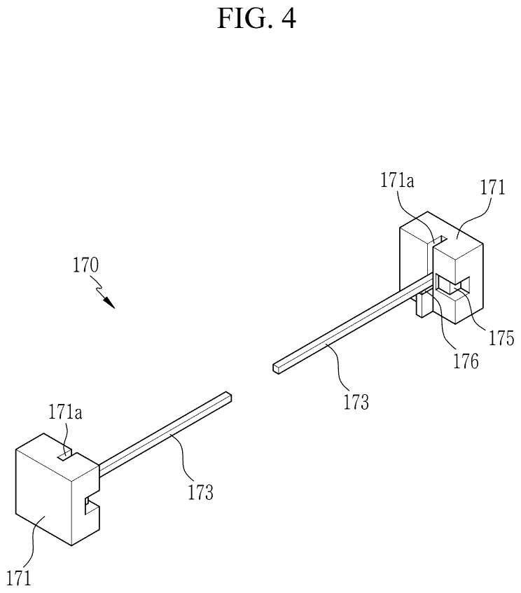

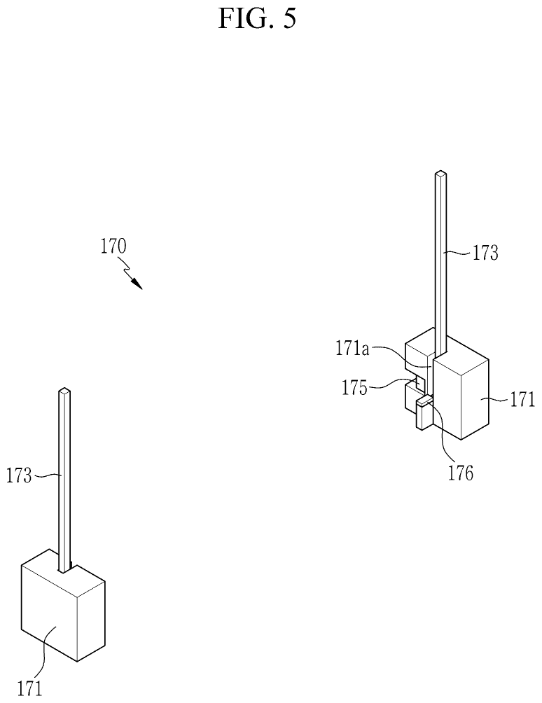

FIG. 4 and FIG. 5 are perspective views showing a travel-stopper applied to a transport system according to an embodiment. FIG. 4 shows the travel-stopper in a closed state. FIG. 5 shows the travel-stopper in an open state.

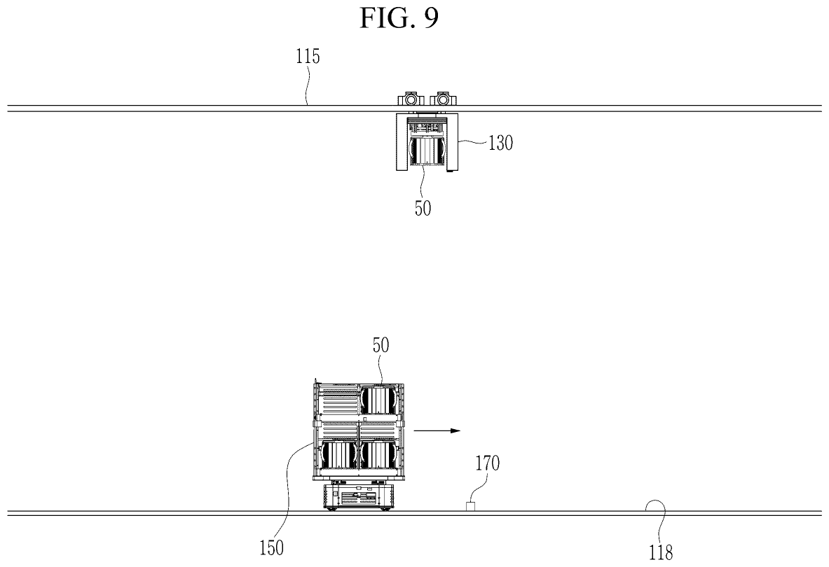

A travel-stopper (e.g., a gate) 170 configured to limit a movement of the AMR 150 may be installed on the floor 118 of the semiconductor fabrication line (see FIG. 9). The travel-stopper 170 may be used when a home position of the AMR 150 is to be used within a particular area, or when the movement of the AMR 150 is to be mechanically restricted due to concerns about malfunction of the AMR 150. The travel-stopper 170 may be installed regardless of the concrete or grating floor surface, and may position the AMR 150 at a designated location. Accordingly, the travel-stopper 170 may be an AMR stopper.

Referring to FIG. 4, the travel-stopper 170 may be provided with a stationary block 171 and an exit prevention bar 173. A first end of the exit prevention bar 173 may be fixed to the stationary block 171, and the stationary block 171 may pivot the exit prevention bar 173. A solenoid motor 175 may be installed in the stationary block 171, and by using the solenoid motor 175, the exit prevention bar 173 may be pivoted around a center of a fixed first end thereof. A guide groove 171a configured to guide the motion of the exit prevention bar 173 may be formed on the stationary block 171. A damper 176 may be installed at one end portion of the guide groove 171a with which the exit prevention bar 173 is to be in contact when coming down. The damper 176 may absorb shock or vibration when the exit prevention bar 173 comes down.

The travel-stopper 170 may include a pair of exit prevention bars 173 that protrude from surfaces of a pair of the stationary blocks 171 facing each other. The pair of stationary blocks 171 may be disposed to be spaced apart from each other by interposing an interval, and between them, the pair of exit prevention bars 173 may be driven to pivot while facing each other, to close or open the travel-stopper 170.

The AMR 150 may include the detecting sensor (e.g., a sensor) 1532 configured to detect the exit prevention bar 173. A non-contact detecting sensor such as a lidar sensor may be applied as the detecting sensor 1532. Alternatively, a contact detecting sensor may be applied as the detecting sensor 1532, and at this time, the contact detecting sensor may be disposed within a bumper of the AMR 150.

The travel-stopper 170 may receive a closing command from the control system before the AMR 150 approaches, and may lower the exit prevention bar 173. In addition, the travel-stopper 170 may lift the exit prevention bar 173 by receiving an opening command from the control system when the interface work between the OHT 130 and the AMR 150 is completed.

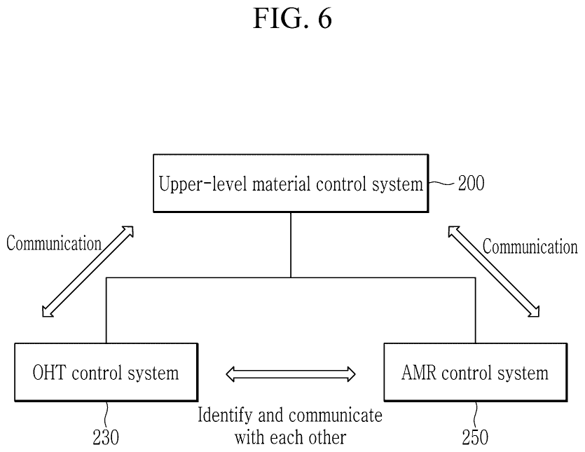

FIG. 6 is a schematic view for explaining a control system applied to a transport system according to an embodiment.

An OHT control system 230 may be provided to control the OHT 130, and an AMR control system 250 may be provided to control the AMR 150. The OHT control system 230 and the AMR control system 250 may be connected to on upper-level material control system 200, and the upper-level material control system 200 may control the OHT control system 230 and the AMR control system 250. The upper-level material control system 200 is a comprehensive system that comprehensively controls other material handling equipment (e.g., tower lifter, stocker, conveyor, or the like).

The upper-level material control system 200 may communicate with each of the OHT control system 230 and the AMR control system 250, and may exchange identification information, control signals and the like. Furthermore, the upper-level material control system 200 may transfer the identification information transferred from the OHT control system 230 to the AMR control system 250, and to the contrary, transfer the identification information transferred from the AMR control system 250 to the OHT control system 230, thereby expanding the functions.

Although not illustrated, each of the disclosed controllers and control systems can include one or more of the following components: at least one hardware processor (e.g., a microprocessor or central processing unit (CPU)) configured to execute computer program instructions to perform various processes and methods, random access memory (RAM) and read only memory (ROM) configured to access and store data and information and computer program instructions, input/output (I/O) devices configured to provide input and/or output to the processing controller 1020 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller or control system. Further, the disclosed controllers and control systems may be independently provided as separate computers or may be variously combined to form one or more computers that perform the functions of one or more of the individual controllers or control systems.

In addition, the OHT control system 230 and the AMR control system 250 may communicate with each other by using respective interfaces, and may exchange the identification information.

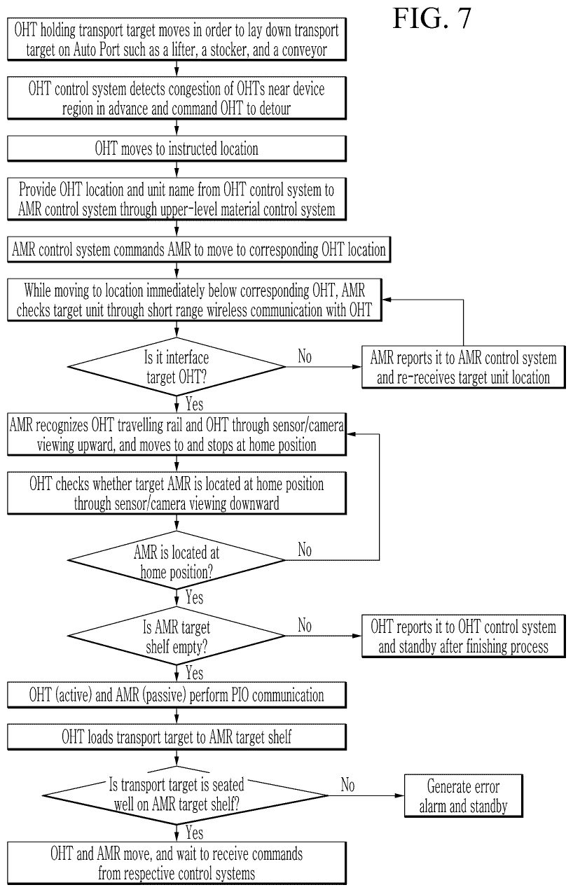

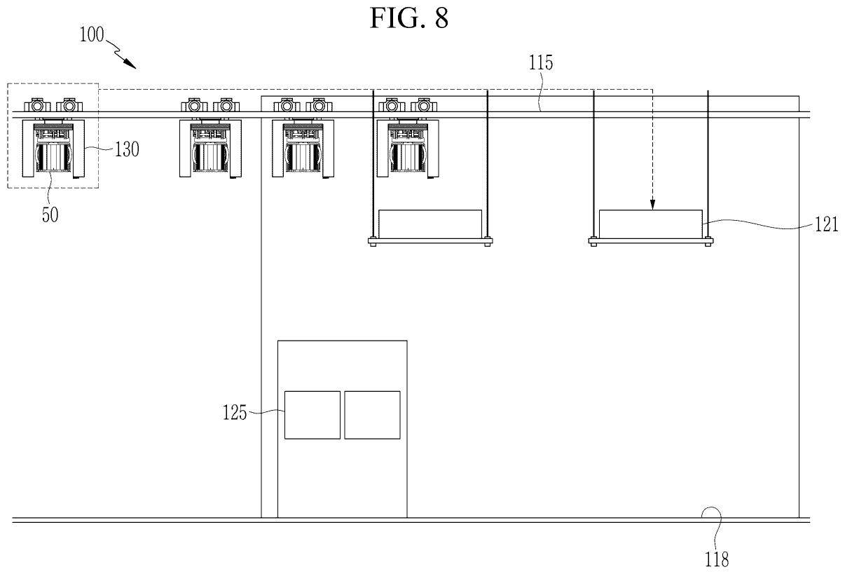

FIG. 7 is a flowchart for explaining the transport target interface method according to another embodiment. FIG. 8 to FIG. 13 are drawings for explaining the transport target interface method using the transport system shown in FIG. 1.

The transport target interface method between the OHT 130, which is the first transport unit, and the AMR 150, which is the second transport unit may be implemented and executed on the transport system 100 according to the flowchart shown in FIG. 7. Although FIG. 7 shows the process of unloading the transport target 50 from the OHT 130 to the AMR 150, the transport target interface method according to the present embodiment may also be applied to the case where the OHT 130 moves to pick up the transport target 50 loaded on the AMR 150, and this may also fall within the scope of the present disclosure.

According to the transport target interface method according to the present embodiment, the transport target 50 is boarded and moved on the OHT 130 configured to move along the travelling rail 115 installed in the semiconductor fabrication line.

The OHT 130 holding the transport target 50 moves to an auto port 121 of the material handling equipment (e.g., tower lifter, stocker, conveyor), in order to unload the transport target 50 (e.g., at a first position). While doing so, in the OHT control system 230 may detect the congestion of other OHTs near the target equipment, in advance. At this time, the OHT control system 230 may command the OHT 130 to move to a detour destination (e.g., a second position), and the OHT 130 may move to the corresponding destination which is the instructed location (see FIG. 8).

Subsequently, the AMR 150 autonomously driving on the floor 118 of the semiconductor fabrication line, in a location lower than the OHT 130, may be prepared.

The OHT control system 230 transfers the information of the location and the unit name of the OHT 130 to the AMR control system 250 through the upper-level material control system 200. The AMR control system 250 may command the AMR 150 to move to the location of corresponding OHT 130. The AMR 150, which has received the command, may move to a position (e.g., a third position) directly below the OHT 130 (see FIG. 9). For example, the AMR 150 may move forward until stopped, using the detecting sensor 1532, by the travel-stopper 170 to be located at a home position that is directly below a home position of the OHT 130.

Subsequently, the OHT 130 and the AMR 150 may sense and communicate with each other, to check the interface target and be located to home positions. For example, the AMR 150 may communicate with the OHT 130 to check whether the location and unit name of the OHT 130 matches the location and unit name received through the upper-level material control system 200.

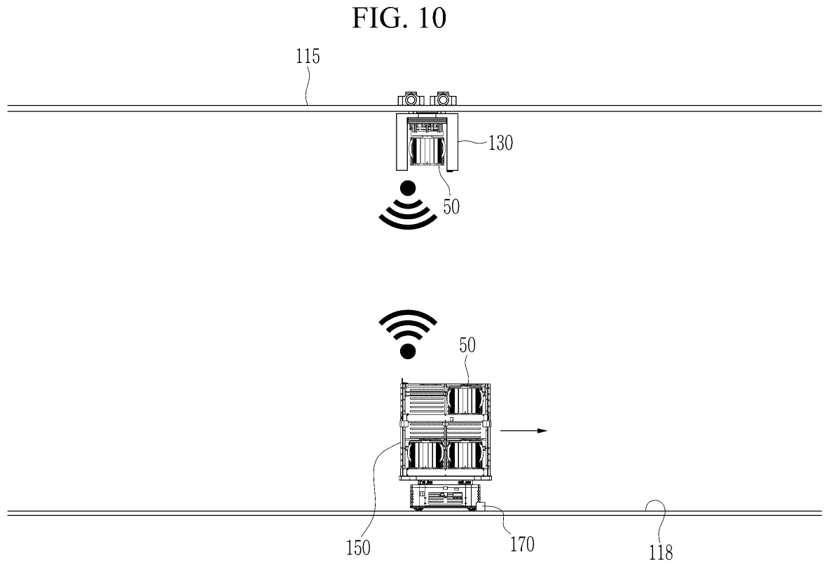

That is, while moving, the AMR 150 may check whether it is a correct target unit by short range wireless communication with the corresponding OHT 130, recognize the travelling rail 115 and the OHT 130, and be located at the home position (see FIG. 10). At this time, when it is not an interface target OHT, the AMR 150 may report it to the AMR control system 250 to re-receive the location of the target unit.

The AMR 150 may recognize the travelling rail 115 and the OHT 130 through a camera or vision sensor viewing upward. The OHT 130 may confirm whether the target AMR 150 is located at the home position through a camera or vision sensor viewing downward.

Subsequently, the transport target 50 is transferred from the OHT 130 to the AMR 150.

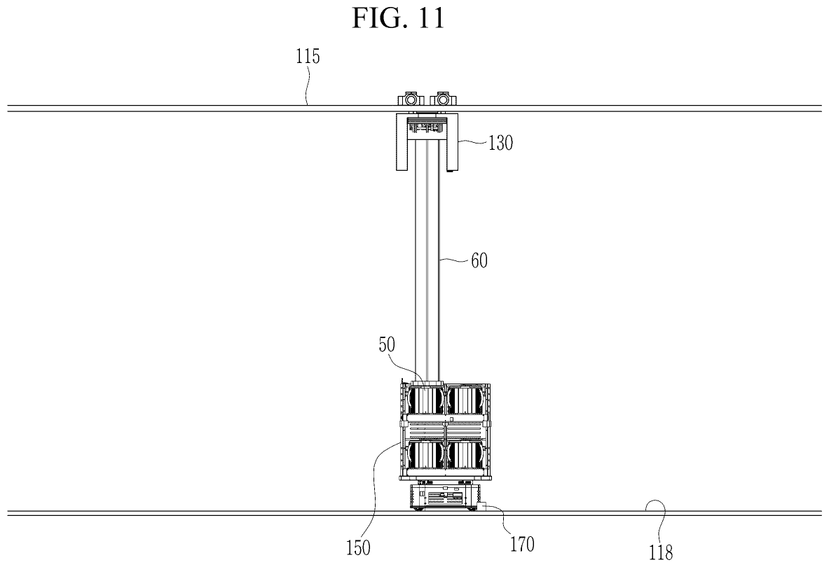

That is, after checking whether the target AMR 150 is located at the home position and whether the shelf to be loaded is empty, the OHT 130 performs the PIO communication with the AMR 150 and performs the loading work. The transport target 50 on the OHT 130 may be lowered by a lifter 60 and may be loaded to the shelf of the AMR 150 (see FIG. 11).

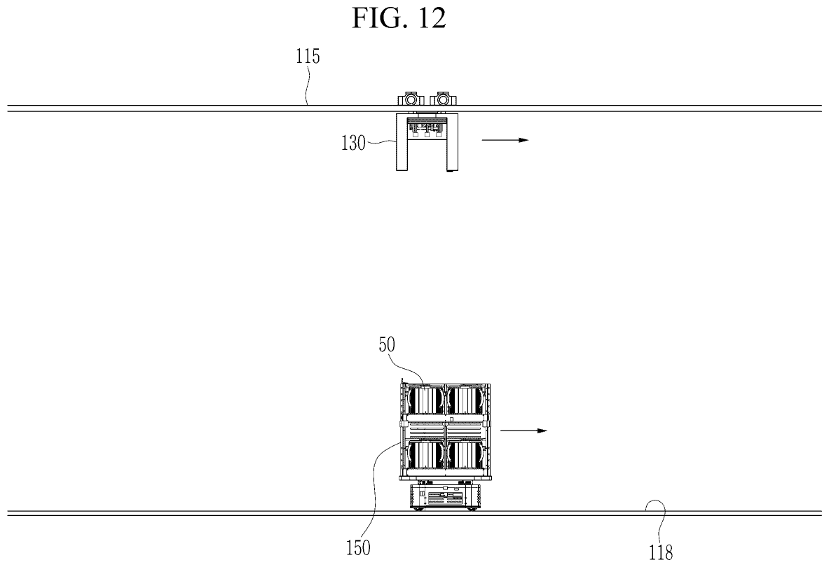

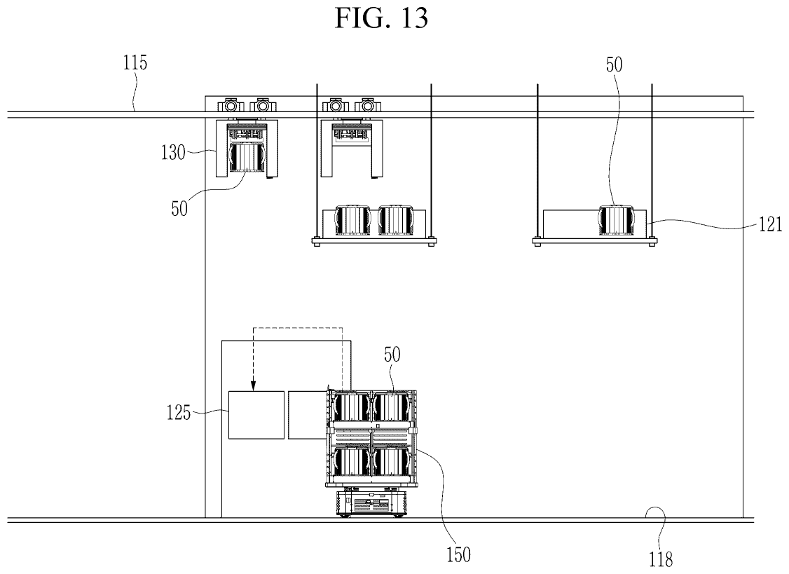

When the transport target 50 is transferred to the AMR 150 well, the OHT 130 and the AMR 150 may move and wait to receive commands of respective control systems (see FIG. 12). At this time, the AMR 150 may transfer the transport target 50 to the location which was an original destination of the OHT 130 by utilizing a dedicated port 125 (see FIG. 13).

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the inventive concept.

What is claimed is:

1. A transport system, comprising:
a first transport unit configured to move along a travelling rail installed in a semiconductor fabrication line, the first transport unit being configured to transport a transport target;
a second transport unit configured to autonomously travel on a floor of the semiconductor fabrication line, in a location lower than the first transport unit;
a first interface installed in the first transport unit and configured to identify and communicate with the second transport unit;
a second interface installed in the second transport unit and configured to identify and communicate with the first transport unit; and
a controller configured to receive signals from the first interface and the second interface, generate and transmit a control signal to the first transport unit and the second transport unit, and control the transport target to be exchanged between the first transport unit and the second transport unit.

2. The transport system of claim 1, wherein the first transport unit comprises an overhead hoist transport (OHT).

3. The transport system of claim 1, wherein the travelling rail is installed on a ceiling of the semiconductor fabrication line, and the first transport unit is adjacent to the ceiling.

4. The transport system of claim 1, wherein the second transport unit comprises an autonomous mobile robot (AMR) including a shelf.

5. The transport system of claim 4, wherein the shelf comprises a plurality of stages that are stacked.

6. The transport system of claim 5, wherein the shelf includes a plurality of shelf sections adjacent to each other in a horizontal direction.

7. The transport system of claim 4, wherein the shelf is moveable in and out in a horizontal direction.

8. The transport system of claim 1, further comprising a gate installed on the floor of the semiconductor fabrication line, the gate comprising an exit prevention bar configured to open and close.

9. The transport system of claim 8, wherein the gate comprises a stationary block to which a first end of the exit prevention bar is fixed and which is configured to pivot the exit prevention bar.

10. The transport system of claim 9, wherein the stationary block has a guide groove configured to guide a motion of the exit prevention bar, and the stationary block comprises a damper in at least one end portion of the guide groove.

11. The transport system of claim 9, wherein the second transport unit comprises a sensor configured to detect the exit prevention bar.

12. The transport system of claim 1, wherein each of the first interface and the second interface comprises a camera or a vision sensor.

13. The transport system of claim 1, wherein each of the first interface and the second interface comprises a parallel input/output (PIO) sensor.

14. The transport system of claim 1, wherein each of the first interface and the second interface comprises an antenna for short-range communication and a wireless LAN card.

15. The transport system of claim 1, wherein:
the controller comprises a first transport unit controller configured to control the first transport unit, a second transport unit controller configured to control the second transport unit, and an upper-level material control system configured to control the first transport unit controller and the second transport unit controller together; and
the first transport unit controller and the second transport unit controller are configured to communicate with each other.

16. A transport system, comprising:
an overhead hoist transport (OHT) configured to move along a travelling rail installed in a semiconductor fabrication line, the OHT being configured to transport a transport target;
an autonomous mobile robot (AMR) configured to autonomously drive below the OHT;
an OHT interface installed in the OHT and configured to identify and communicate with the AMR;
an AMR interface installed in the AMR and configured to identify and communicate with the OHT; and
a controller configured to receive signals from the OHT interface and the AMR interface, generate and transmit a control signal to the OHT and the AMR, and control the transport target to be exchanged between the OHT and the AMR.

17. The transport system of claim 16, wherein the AMR includes a shelf configured to store the transport target.

18. The transport system of claim 16, further comprising a gate installed on a floor of the semiconductor fabrication line, the gate comprising an exit prevention bar configured to open and close.

19. The transport system of claim 16, wherein each of the OHT interface and the AMR interface comprises a camera or a vision sensor, a parallel input/output (PIO) sensor, an antenna for short-range communication, and a wireless LAN card.

20. The transport system of claim 16, wherein:
the controller comprises an OHT controller configured to control the OHT, an AMR controller configured to control the AMR, and an upper-level material control system configured to control the OHT controller and the AMR controller together; and
the OHT controller and the AMR controller are configured to communicate with each other.
